(19) United States
(12) Patent Application Publication
(10) Pub. No.: US 2022/0399478 A1
(43) Pub. Date: Dec. 15, 2022

(54) MICRO LIGHT-EMITTING FILM STRUCTURE AND METHOD FOR MANUFACTURING THE SAME

(71) Applicant: EPILEDS TECHNOLOGIES, INC., Tainan City (TW)

(72) Inventors: Ming-Sen HSU, Tainan City (TW); Li-Wei HUNG, Tainan City (TW); Hsin-Liang YEH, Tainan City (TW); Wei-Chen CHIEN, Tainan City (TW)

(21) Appl. No.: 17/457,439

(22) Filed: Dec. 3, 2021

(30) Foreign Application Priority Data
Jun. 15, 2021 (TW) 110121615

(51) Int. Cl. H01L 33/38; H01L 33/32; H01L 33/10; H01L 33/00

(52) U.S. Cl. CPC H01L 33/382; H01L 33/32; H01L 33/10; H01L 33/0093; H01L 33/0075; H01L 2933/0016

(57) ABSTRACT

A micro light-emitting film structure includes a first conductivity type semiconductor film, a light-emitting film, a second conductivity type semiconductor film, a first contact electrode, and a second contact electrode. The first conductivity type semiconductor film has first and second surfaces opposite to each other. The second surface includes an asperity. A height difference of relief of the asperity is less than or equal to 1 μm. The light-emitting film is disposed on the first surface. The second conductivity type semiconductor film is connected to the light-emitting film sandwiched between the second conductivity type semiconductor film and the first conductivity type semiconductor film. The first contact electrode is connected to the first conductivity type semiconductor film. The second contact electrode is connected to the second conductivity type semiconductor film. A thickness of the micro light-emitting film structure is equal to or smaller than 10 μm.

### RELATED APPLICATIONS

This application claims priority to Taiwan Application Serial Number 110121615, filed Jun. 15, 2021, which is herein incorporated by reference.

### BACKGROUND

### Field of Invention

The present disclosure relates to a technique for manufacturing a light-emitting structure, and more particularly, to a micro light-emitting film structure.

### Description of Related Art

When manufacturing a micro light-emitting structure, such as a micro light-emitting diode, a light-emitting epitaxial structure is usually grown on a growth substrate firstly, and then contact electrodes are disposed on the light-emitting epitaxial structure. Next, the contact electrodes are bonded to a temporary substrate. Then, the growth substrate is stripped from the light-emitting epitaxial structure by using the temporary substrate as a structural support to form a micro light-emitting structure composed of the light-emitting epitaxial structure and the contact electrodes. Subsequently, the micro light-emitting structure can be transferred to a panel.

The epitaxial films of the micro light-emitting structure are usually composed of gallium nitride and the like, and gallium nitride is more difficult to etch. In addition, a size of the micro light-emitting structure is quite small, and a thickness of each layer of epitaxial film is very thin. Therefore, when the epitaxial film including the light-extracting surface of the micro light-emitting structure is roughened, the underlying structure is easily damaged.

### SUMMARY

Therefore, one objective of the present disclosure is to provide a micro light-emitting film structure and a method for manufacturing the same, in which when an adhesive material is used to bond a micro light-emitting film structure on a surface of a temporary substrate, the adhesive material covers a side surface of a first conductive semiconductor film, such that when a light-extracting surface of the first conductivity type semiconductor film is roughened, the films underlying the first conductivity type semiconductor film are prevented from being damaged, thereby increasing the process yield.

Another objective of the present disclosure is to provide a micro light-emitting film structure and a method for manufacturing the same, which may form a asperity including many microstructures on a light-extracting surface of a first conductivity type semiconductor film, such that the internal reflection of the micro light-emitting film structure is reduced, and the light extraction rate of the micro light-emitting film structure is effectively enhanced, thereby increasing the brightness of the micro light-emitting film structure.

According to the aforementioned objectives of the present disclosure, a micro light-emitting film structure is provided. The micro light-emitting film structure includes a first conductivity type semiconductor film, a light-emitting film, a second conductivity type semiconductor film, a first contact electrode, and a second contact electrode. The first conductivity type semiconductor film has a first surface and a second surface, which are opposite to each other. The second surface of the first conductivity type semiconductor film includes an asperity, and a height difference of relief of the asperity is less than or equal to 1 μm. The light-emitting film is disposed on the first surface of the first conductivity type semiconductor film. The second conductivity type semiconductor film is connected to the light-emitting film, wherein the light-emitting film is sandwiched between the second conductivity type semiconductor film and the first conductivity type semiconductor film. A conductivity type of the first conductivity type semiconductor film is different from a conductivity type of the second conductivity type semiconductor film. The first contact electrode is connected to the first conductivity type semiconductor film. The second contact electrode is connected to the second conductivity type semiconductor film. A length or a diameter of the micro light-emitting film structure is less than about 100 μm, and a thickness of the micro light-emitting film structure is equal to or less than about 10 μm.

According to one embodiment of the present disclosure, the asperity includes various microstructures, each of the microstructures includes a top and a bottom, and a height difference from the top to the bottom of each of the microstructures is between 600 nm and 1 μm.

According to one embodiment of the present disclosure, the asperity includes various microstructures, each of the microstructures includes a top and a bottom, and a height difference from the top to the bottom of each of the microstructures is between 200 nm and 1 μm.

According to one embodiment of the present disclosure, the first conductivity type semiconductor film is an N-type GaN film, and the second conductivity type semiconductor film is a P-type GaN film.

According to one embodiment of the present disclosure, the first surface of the first conductivity type semiconductor film includes a first portion and a second portion, the light-emitting film is disposed on the first portion of the first surface, and the first contact electrode is disposed on the second portion of the first surface and is physically separated from the light-emitting film.

According to one embodiment of the present disclosure, the first contact electrode is disposed on a portion of the second surface of the first conductivity type semiconductor film, and the second contact electrode and the first contact electrode are respectively located at two opposite sides of the second conductivity type semiconductor film. The micro light-emitting film structure further includes a reflective film and a temporary substrate. The reflective film is disposed between the second conductivity type semiconductor film and the second contact electrode. The temporary substrate is sandwiched between the reflective film and the second contact electrode.

According to the aforementioned objectives of the present disclosure, a method for manufacturing a micro light-emitting film structure is further provided. In this method, a first conductivity type semiconductor film is formed on a growth substrate. The first conductivity type semiconductor film has a first surface and a second surface, which are opposite to each other. The first surface includes a first portion and a second portion, and the second surface is connected to the growth substrate. A light-emitting film is formed on the first portion of the first surface of the first conductivity type semiconductor film. A second conductivity type semiconductor film is formed on the light-emitting film. A conductivity type of the first conductivity type semiconductor film is different from a conductivity type of the second conductivity type semiconductor film. A first contact electrode is formed on the second portion of the first surface of the first conductivity type semiconductor film, in which the first contact electrode is physically separated from the light-emitting film. A second contact electrode is formed on the second conductivity type semiconductor film. The first conductivity type semiconductor film, the light-emitting film, the second conductivity type semiconductor film, the first contact electrode, and the second contact electrode form a micro light-emitting film structure. The micro light-emitting film structure is bonded onto a surface of a temporary substrate by using an adhesive material, in which the first contact electrode and the second contact electrode face and are bonded to the surface. The adhesive material extends at least from the surface to a side surface of the first conductivity type semiconductor film. The growth substrate is removed. An asperity is formed on the second surface of the first conductivity type semiconductor film, in which a height difference of relief of the asperity is less than or equal to 1 μm. The temporary substrate is removed. The adhesive material is removed.

According to one embodiment of the present disclosure, the asperity includes various microstructures, each of the microstructures includes a top and a bottom, and a height difference from the top to the bottom of each of the microstructures is between 200 nm and 1 μm.

According to one embodiment of the present disclosure, the first conductivity type semiconductor film is an N-type GaN film, and the second conductivity type semiconductor film is a P-type GaN film.

According to one embodiment of the present disclosure, forming the asperity includes performing a roughening treatment on the second surface of the first conductivity type semiconductor film.

According to one embodiment of the present disclosure, performing the roughening treatment includes using a dry etching technique, a wet etching technique, or a photolithograph technique.

According to one embodiment of the present disclosure, the growth substrate includes various surface microstructures. Forming the first conductivity type semiconductor film includes covering and bonding the surface microstructures with the second surface of the first conductivity type semiconductor film, and forming the asperity includes separating the second surface from the surface microstructures.

According to one embodiment of the present disclosure, forming the asperity further includes performing a roughening treatment on the second surface of the first conductivity type semiconductor film after the second surface is separated from the surface microstructures.

According to the aforementioned objectives of the present disclosure, a method for manufacturing a micro light-emitting film structure is further provided. In this method, a first conductivity type semiconductor film is formed on a growth substrate. The first conductivity type semiconductor film has a first surface and a second surface, which are opposite to each other, and the second surface is connected to the growth substrate. A light-emitting film is formed on the first surface of the first conductivity type semiconductor film. A second conductivity type semiconductor film is formed on the light-emitting film. A conductivity type of the first conductivity type semiconductor film is different from a conductivity type of the second conductivity type semiconductor film. A reflective film is formed on the second conductivity type semiconductor film. The reflective film is bonded onto a surface of a temporary substrate by using an adhesive material. The adhesive material extends at least from the surface to a side surface of the first conductivity type semiconductor film. The growth substrate is removed. An asperity is formed on the second surface of the first conductivity type semiconductor film, in which a height difference of relief of the asperity is less than or equal to 1 μm. A first contact electrode is formed on a portion of the second surface of the first conductivity type semiconductor film. A second contact electrode is formed on the temporary substrate, in which the temporary substrate is located between the reflective film and the second contact electrode.

According to one embodiment of the present disclosure, the asperity includes various microstructures, each of the microstructures includes a top and a bottom, and a height difference from the top to the bottom of each of the microstructures is between 200 nm and 1 μm.

According to one embodiment of the present disclosure, the first conductivity type semiconductor film is an N-type GaN film, and the second conductivity type semiconductor film is a P-type GaN film.

According to one embodiment of the present disclosure, forming the asperity includes performing a roughening treatment on the second surface of the first conductivity type semiconductor film.

According to one embodiment of the present disclosure, performing the roughening treatment includes using a dry etching technique, a wet etching technique, or a photolithograph technique.

According to one embodiment of the present disclosure, the growth substrate includes various surface microstructures. Forming the first conductivity type semiconductor film includes covering and bonding the surface microstructures with the second surface of the first conductivity type semiconductor film, and forming the asperity includes separating the second surface from the surface microstructures.

According to one embodiment of the present disclosure, forming the asperity further includes performing a roughening treatment on the second surface of the first conductivity type semiconductor film after the second surface is separated from the surface microstructures.

### BRIEF DESCRIPTION OF THE DRAWINGS

The aforementioned and other objectives, features, advantages and examples of the present disclosure can be more fully understood by reading the following detailed description of the embodiment, with reference made to the accompanying drawings as follows:

FIG. 1 is a schematic cross-sectional view of a micro light-emitting film structure in accordance with a first embodiment of the present disclosure;

FIG. 2 is a schematic cross-sectional view of a micro light-emitting film structure in accordance with a second embodiment of the present disclosure;

FIGS. 3A to 3E are schematic cross-sectional views of various stages showing a process for manufacturing a micro light-emitting film structure in accordance with the first embodiment of the present disclosure;

FIGS. 4A to 4C are schematic cross-sectional views of various stages showing another process for manufacturing a micro light-emitting film structure in accordance with the first embodiment of the present disclosure;

FIGS. 5A to 5C are schematic cross-sectional views of various stages showing a process for manufacturing a micro light-emitting film structure in accordance with the second embodiment of the present disclosure; and

FIGS. 6A to 6C are schematic cross-sectional views of various stages showing another process for manufacturing a micro light-emitting film structure in accordance with the second embodiment of the present disclosure.

### DETAILED DESCRIPTION

The following disclosure provides many different embodiments for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features.

Spatially relative terms, such as “beneath,” “below,” “lower,” “above,” “upper,” and the like, may be used herein for ease of description to describe one element or feature's relationship to another element(s) or feature(s) as illustrated in the figures. In addition to the orientation depicted in the figures, the spatially relative terms are intended to encompass different orientations of the device in use or operation.

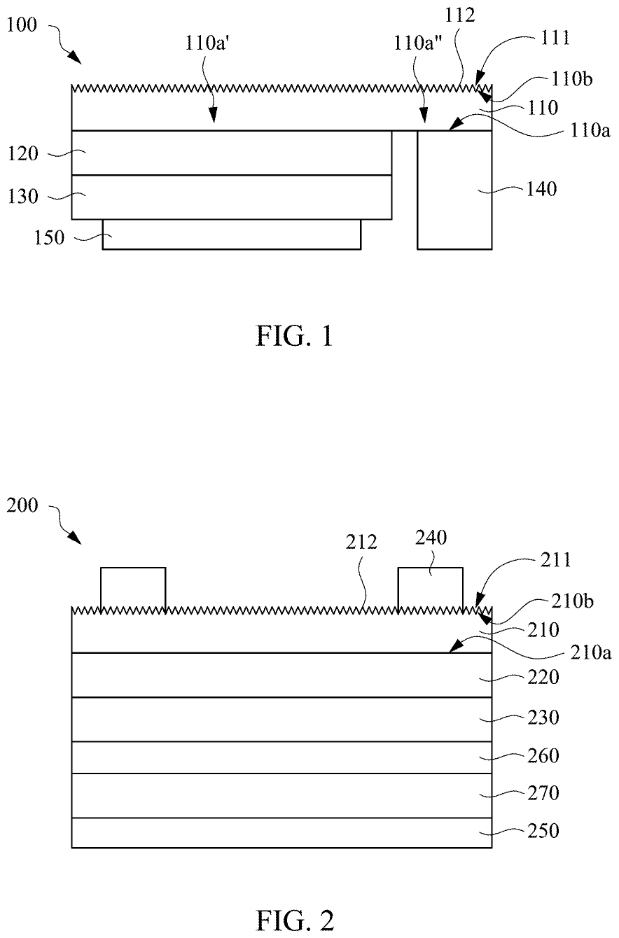

Refer to FIG. 1. FIG. 1 is a schematic cross-sectional view of a micro light-emitting film structure in accordance with a first embodiment of the present disclosure. A micro light-emitting film structure 100 of the present embodiment may be, for example, a micro light-emitting diode structure. The micro light-emitting diode structure of the present disclosure may mean that its length, width (or radial dimension), and height (or thickness) are in a range from 1 μm to 100 μm. For example, a length or a diameter of the micro light-emitting film structure 100 may be smaller than about 100 μm. In some exemplary examples, a thickness of the micro light-emitting film structure 100 is equal to or smaller than about 10 μm.

The micro light-emitting film structure 100 of the present embodiment is a flip chip light-emitting structure. In some examples, the micro light-emitting film structure 100 may mainly include a first conductivity type semiconductor film 110, a light-emitting film 120, a second conductivity type semiconductor film 130, a first contact electrode 140, and a second contact electrode 150.

A conductivity type of the first conductivity type semiconductor film 110 may depend on a product design. For example, the conductivity type of the first conductivity type semiconductor film 110 may be N type or P type. In addition, a material of the first conductivity type semiconductor film 110 may, for example, include gallium nitride (GaN) or GaN-based materials. In some exemplary examples, the first conductivity type semiconductor film 110 is an N-type GaN film. The first conductivity type semiconductor film 110 has a first surface 110a and a second surface 110b, in which the first surface 110a and the second surface 110b are respectively located on two opposite sides of the first conductivity type semiconductor film 110. The first surface 110a of the first conductivity type semiconductor film 110 includes a first portion 110a′ and a second portion 110a″.

The second surface 110b of the first conductivity type semiconductor film 110 includes an asperity 111 to increase light extraction efficiency. In some examples, a height difference of relief of the asperity 111 is less than or equal to 1 μm. The asperity 111 includes many microstructures 112. Viewing the second surface 110b from top of the second surface 110b of the first conductivity type semiconductor film 110, these microstructures 112 may be regular or periodically arranged polygonal or circular in the plane. In other examples, these microstructures 112 may be arranged irregularly or non-periodically on the second surface 110b. Due to the small size of the micro light-emitting film structure 100, a thickness of the first conductivity type semiconductor film 110 is relatively thin. Heights of the microstructures 112 depends on the thickness of the first conductivity type semiconductor film 110. In some exemplary examples, a height difference of each of the microstructures 112 from the top to the bottom is between about 600 nm and about 1 μm. In other embodiments, a height difference of each of the microstructures 112 from the top to the bottom is between about 200 nm and about 1 μm.

The light-emitting film 120 is disposed on the first portion 110a′ of the first surface 110a of the first conductivity type semiconductor film 110, such that the light-emitting film 120 and the microstructures 112 are respectively located at two opposite sides of the first conductivity type semiconductor film 110. The light-emitting film 120 may, for example, include a multiple quantum well (MQW) structure. In some exemplary examples, the light-emitting film 120 is formed by alternatively stacking GaN and GaN-based materials.

The second conductivity type semiconductor film 130 is located on one side of the light-emitting film 120 and is connected to the light-emitting film 120. In addition, the first conductivity type semiconductor film 110 and the second conductivity type semiconductor film 130 are respectively located at two opposite sides of the light-emitting film 120, such that the light-emitting film 120 is sandwiched between the first conductivity type semiconductor film 110 and the second conductivity type semiconductor film 130. A conductivity type of the second conductivity type semiconductor film 130 is different from the conductivity type of the first conductivity type semiconductor film 110. One of the first conductivity type semiconductor film 110 and the second conductivity type semiconductor film 130 is N type, and the other one is P type. For example, the first conductivity type semiconductor film 110 is N type, and the second conductivity type semiconductor film 130 is P type. In addition, a material of the second conductivity type semiconductor film 130 may include GaN or GaN-based materials. In some exemplary examples, the second conductivity type semiconductor film 130 is a P-type GaN film.

The first contact electrode 140 is disposed on the second portion 110a″ of the first surface 110a of the first conductivity type semiconductor film 110, and is connected to the first conductivity type semiconductor film 110, thereby electrically connecting with the first conductivity type semiconductor film 110. In addition, the first contact electrode 140 is physically separated from the light-emitting film 120, i.e. they are not in contact with each other. For example, a material of the first contact electrode 140 may include any one of titanium (Ti), nickel (Ni), aluminum (Al), palladium (Pd), rhodium (Rh), platinum (Pt), gold (Au), and chromium (Cr) or an alloy structure thereof.

The second contact electrode 150 is disposed at one side of the second conductivity type semiconductor film 130, and the second contact electrode 150 and the light-emitting film 120 are respectively located at two opposite sides of the second conductivity type semiconductor film 130. The second contact electrode 150 is connected to the second conductivity type semiconductor film 130, thereby electrically connecting with the second conductivity type semiconductor film 130. For example, a material of the second contact electrode 150 may include any one of Ti, Ni, Al, Pd, Rh, Pt, Au, and Cr or an alloy structure thereof.

The second surface 110b of the first conductivity type semiconductor film 110 is a light-extracting surface of the micro light-emitting film structure 100, and is provided with the asperity 111 including many microstructures 112. These microstructures 112 can destroy the total reflection of the light emitted from the light-emitting film 120 to the second surface 110b, and can reduce the internal reflection of the light in the micro light-emitting film structure 100. Thus, a light extraction rate of the micro light-emitting film structure 100 is greatly increased, and an effect of enhancing the brightness of the micro light-emitting film structure 100 is achieved. In addition, the light-extracting surface of the micro light-emitting film structure 100 is provided with many microstructures 112, such that the micro light-emitting film structure 100 can be assembled on a panel and other devices by using a fluid assembly method.

Refer to FIG. 2. FIG. 2 is a schematic cross-sectional view of a micro light-emitting film structure in accordance with a second embodiment of the present disclosure. A micro light-emitting film structure 200 of the present disclosure may also be a micro light-emitting diode structure. For example, a length or a diameter of the micro light-emitting film structure 200 may be smaller than about 100 μm. For example, a thickness of the micro light-emitting film structure 200 may be equal to or smaller than about 10 μm.

The micro light-emitting film structure 200 of the present embodiment is a vertical light-emitting structure. In some examples, the micro light-emitting film structure 200 may mainly include a first conductivity type semiconductor film 210, a light-emitting film 220, a second conductivity type semiconductor film 230, a first contact electrode 240, and a second contact electrode 250.

For example, the conductivity type of the first conductivity type semiconductor film 210 may be N type or P type. A material of the first conductivity type semiconductor film 210 may, for example, include GaN or GaN-based materials. In some exemplary examples, the first conductivity type semiconductor film 210 is an N-type GaN film. The first conductivity type semiconductor film 210 has a first surface 210a and a second surface 210b, which are respectively located on two opposite sides of the first conductivity type semiconductor film 210.

The second surface 210b of the first conductivity type semiconductor film 210 includes an asperity 211 to increase light extraction efficiency. In some examples, a height difference of relief of the asperity 211 is less than or equal to 1 μm. The asperity 211 includes many microstructures 212. Viewing the second surface 210b from top of the second surface 210b of the first conductivity type semiconductor film 210, these microstructures 212 may be regular or periodically arranged polygonal or circular in the plane. In other examples, these microstructures 212 may be arranged irregularly or non-periodically on the second surface 210b. In some exemplary examples, a height difference of each of the microstructures 212 from the top to the bottom is between about 600 nm and about 1 μm. In other embodiments, a height difference of each of the microstructures 212 from the top to the bottom is between about 200 nm and about 1 μm.

The light-emitting film 220 is disposed on of the first surface 210a of the first conductivity type semiconductor film 210. The light-emitting film 220 may, for example, include a multiple quantum well structure. In some exemplary examples, the light-emitting film 220 is formed by alternatively stacking GaN and GaN-based materials.

The second conductivity type semiconductor film 230 is located on one side of the light-emitting film 220 and is connected to the light-emitting film 220. In addition, the light-emitting film 220 is sandwiched between the first conductivity type semiconductor film 210 and the second conductivity type semiconductor film 230. The second conductivity type semiconductor film 230 and the first conductivity type semiconductor film 210 have different conductivity types. One of the first conductivity type semiconductor film 210 and the second conductivity type semiconductor film 230 is N type, and the other one is P type. For example, the first conductivity type semiconductor film 210 is N type, and the second conductivity type semiconductor film 230 is P type. A material of the second conductivity type semiconductor film 230 may include GaN or GaN-based materials. In some exemplary examples, the second conductivity type semiconductor film 230 is a P-type GaN film.

The first contact electrode 240 is disposed on a portion of the second surface 210b of the first conductivity type semiconductor film 210, and is connected to the first conductivity type semiconductor film 210, thereby electrically connecting with the first conductivity type semiconductor film 210. For example, a material of the first contact electrode 240 may include any one of Ti, Ni, Al, Pd, Rh, Pt, Au, and Cr or an alloy structure thereof.

The second contact electrode 250 is disposed at one side of the second conductivity type semiconductor film 230, and the second contact electrode 250 and the first contact electrode 240 are respectively located at two opposite sides of the second conductivity type semiconductor film 230. For example, a material of the second contact electrode 250 may include any one of Ti, Ni, Al, Pd, Rh, Pt, Au, and Cr or an alloy structure thereof.

In some examples, the micro light-emitting film structure 200 may further include a reflective film 260. The reflective film 260 is disposed on one side of the second conductivity type semiconductor film 230, and is between the second conductivity type semiconductor film 230 and the second contact electrode 250. The reflective film 260 may be a conductive film. The second contact electrode 250 is indirectly connected to the second conductive type semiconductor film 230 through the reflective film 260, and thus is electrically connected to the second conductive type semiconductor film 230. The reflective film 260 can reflect light directed to the reflective film 260.

Optionally, the micro light-emitting film structure 200 may further include a temporary substrate 270. The temporary substrate 270 is sandwiched between the reflective film 260 and the second contact electrode 250. The temporary substrate 270 may be a conductive substrate. The second contact electrode 250 is indirectly connected to the second conductive type semiconductor film 230 sequentially through the temporary substrate 270 and the reflective film 260, and thus is electrically connected to the second conductive type semiconductor film 230.

The second surface 210b, which includes the asperity 211, of the first conductivity type semiconductor film 210 is a light-extracting surface of the micro light-emitting film structure 200. The microstructures 212 of the asperity 211 can destroy the total reflection of the light emitted from the light-emitting film 220 to the second surface 210b, and can reduce the internal reflection of the light in the micro light-emitting film structure 200. Thus, a light extraction rate of the micro light-emitting film structure 200 is greatly enhanced, thereby effectively increasing the brightness of the micro light-emitting film structure 200. The light-extracting surface of the micro light-emitting film structure 200 is provided with the asperity 211, such that the micro light-emitting film structure 200 can be assembled on a panel and other devices by using a fluid assembly method.

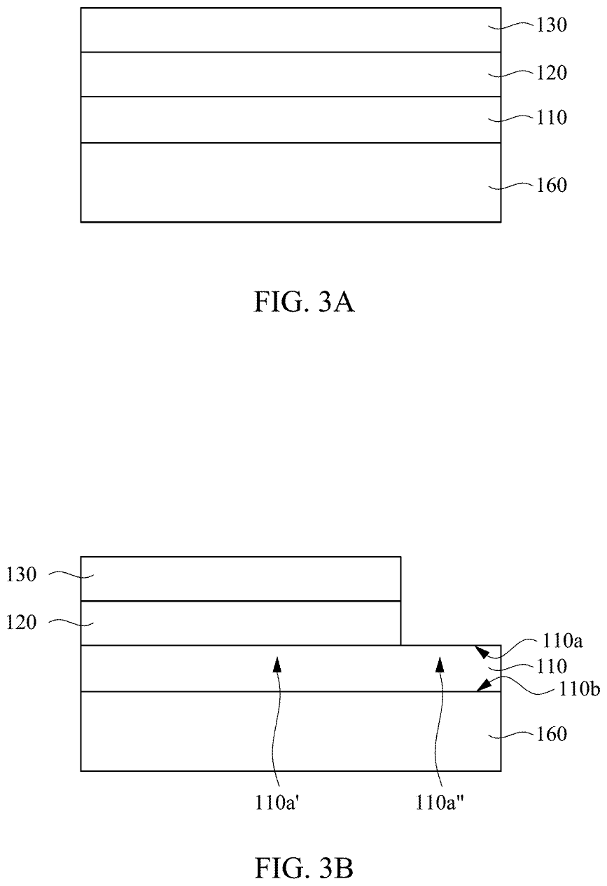

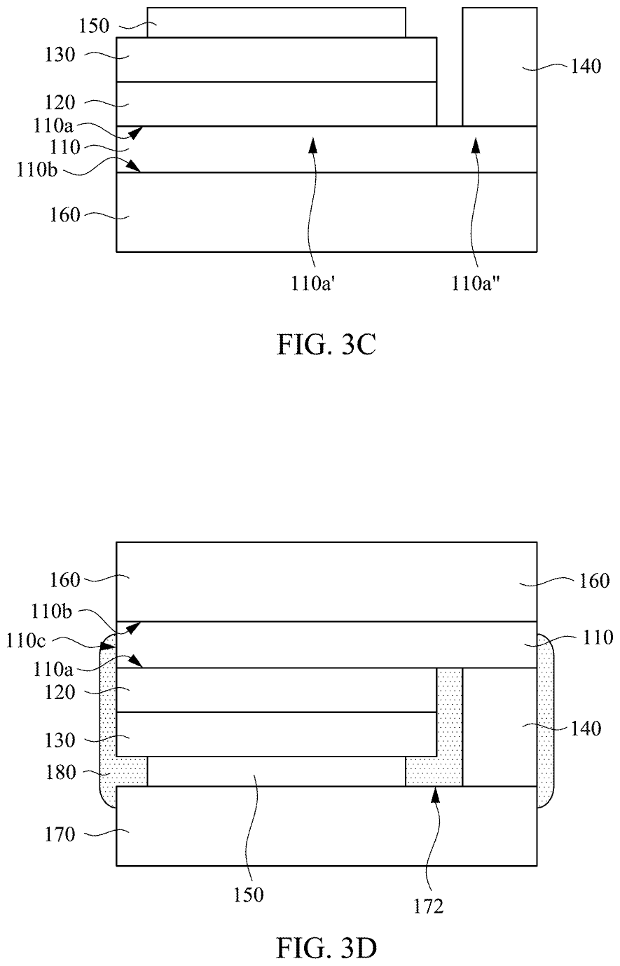

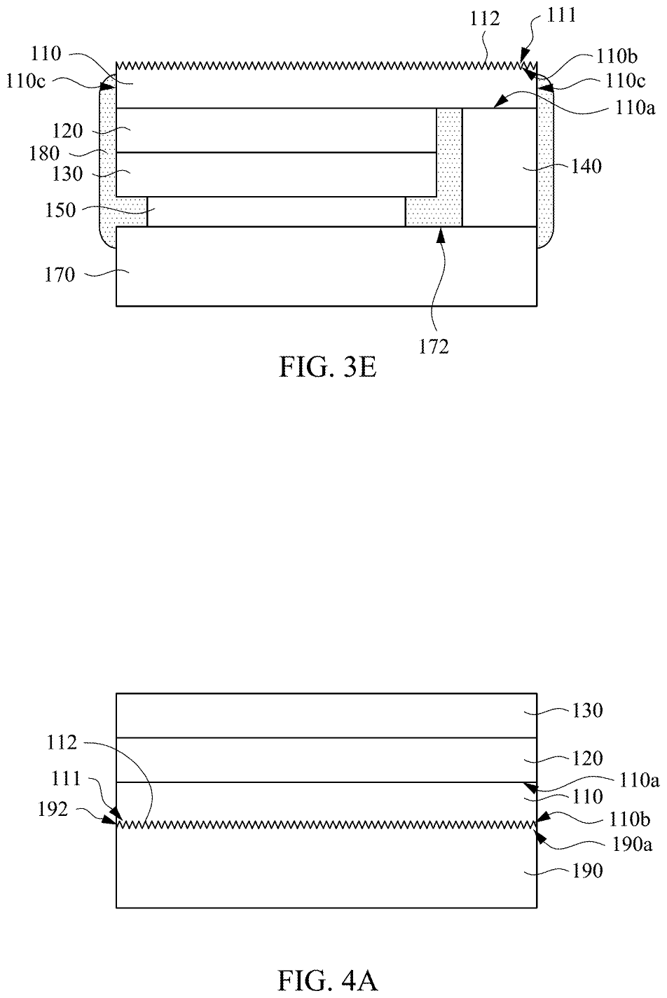

Refer to FIGS. 3A to 3E. FIGS. 3A to 3E are schematic cross-sectional views of various stages showing a process for manufacturing a micro light-emitting film structure in accordance with the first embodiment of the present disclosure. As shown in FIG. 3A, when the micro light-emitting film structure 100 shown in FIG. 1 is manufactured, a growth substrate 160 may be provided firstly. Next, the first conductivity type semiconductor film 110 is formed on the growth substrate 160 by using, for example, an epitaxial growth method. The second surface 110b of the first conductivity type semiconductor film 110 is connected to the growth substrate 160.

Then, the light-emitting film 120 is formed on the first surface 110a of the first conductivity type semiconductor film 110 by using, for example, an epitaxial growth method. As shown in FIG. 3A, the second conductivity type semiconductor film 130 is formed on the light-emitting film 120 by using, for example, an epitaxial growth method. Then, as shown in FIG. 3B, a portion of the second conductivity type semiconductor film 130 and a portion of the light-emitting film 120 are removed by using, for example, a photolithograph process and an etching process, until the second portion 110a″ of the first surface 110a of the first conductivity type semiconductor film 110 is exposed. Thus, the light-emitting film 120 and the second conductivity type semiconductor film 130 are sequentially stacked on the first portion 110a′ of the first surface 110a of the first conductivity type semiconductor film 110.

Next, as shown in FIG. 3C, the first contact electrode 140 may be formed on the exposed second portion 110a″ of the first surface 110a of the first conductivity type semiconductor film 110 by using, for example, an evaporation method. The first contact electrode 140 and the light-emitting film 120 are physically separated from each other. Similarly, the second contact electrode 150 may be formed on the second conductive type semiconductor film 130 by using, for example, an evaporation method. The formation sequence of the first contact electrode 140 and the second contact electrode 150 may be adjusted according to requirements, that is, the second contact electrode 150 may be formed firstly, and then the first contact electrode 140 may be formed. The first conductive type semiconductor film 110, the light-emitting film 120, the second conductive type semiconductor film 130, the first contact electrode 140, and the second contact electrode 150 form the micro light-emitting film structure 100 shown in FIG. 1.

Then, a temporary substrate 170 may be firstly provided. The temporary substrate 170 may be any substrate that can provide support for the micro light-emitting film structure 100 to facilitate the subsequent peeling of the growth substrate 160. As shown in FIG. 3D, the structure shown in FIG. 3C is turned upside down, and the micro light-emitting film structure 100 is bonded to a surface 172 of the temporary substrate 170 by using an adhesive material 180. The first contact electrode 140 and the second contact electrode 150 pass through the adhesive material 180, face the surface 172 of the temporary substrate 170, and are bonded to the surface 172 of the temporary substrate 170. The adhesive material 180 may be any colloid, such as laser glue and polydimethylsiloxane (PDMS). The adhesive material 180 extends at least from the surface 172 of the temporary substrate 170 to a side surface 110c of the first conductivity type semiconductor film 110.

After the micro light-emitting film structure 100 is bonded to the surface 172 of the temporary substrate 170, the growth substrate 160 can be removed by using the temporary substrate 170 as a support. The growth substrate 160 may be peeled off by using a laser lift-off method. Any type of laser, such as diode-pumped solid-state laser (DPSS) or excimer laser, can be used to strip the growth substrate 160.

After the growth substrate 160 is removed, the second surface 110b of the first conductivity type semiconductor film 110 may be exposed. Next, as shown in FIG. 3E, the asperity 111 is formed on the second surface 110b of the first conductivity type semiconductor film 110 to enhance light extracting efficiency. The asperity 111 includes many microstructures 112. In some examples, the microstructures 112 may be formed by performing a roughening treatment on the second surface 110b of the first conductive type semiconductor film 110. The roughening treatment may be performed by using, for example, a dry etching technique, a wet etching technique, or a photolithography technique. For example, a reactive ion etching (RIE) process may be used to form the asperity 111 on the second surface 110b of the first conductive type semiconductor film 110. During the roughening treatment, the etching process or the photolithography process may be controlled, so that the height difference of relief of the asperity 111 is less than or equal to 1 μm.

Since the adhesive material 180 extends to cover at least a portion of the side surface 110c of the first conductive type semiconductor film 110, when the second surface 110b of the first conductive type semiconductor film 110 is roughened, the adhesive material 180 can protect a portion of the first conductive type semiconductor film 110 as well as the underlying light-emitting film 120 and the second conductive type semiconductor film 130 from damage. Thus, the process yield is enhanced.

Then, the temporary substrate 170 and the adhesive material 180 may be removed to substantially complete the micro light-emitting film structure 100 shown in FIG. 1. In some examples, the temporary substrate 170 may be removed by removing the adhesive material 180 from the micro light-emitting film structure 100.

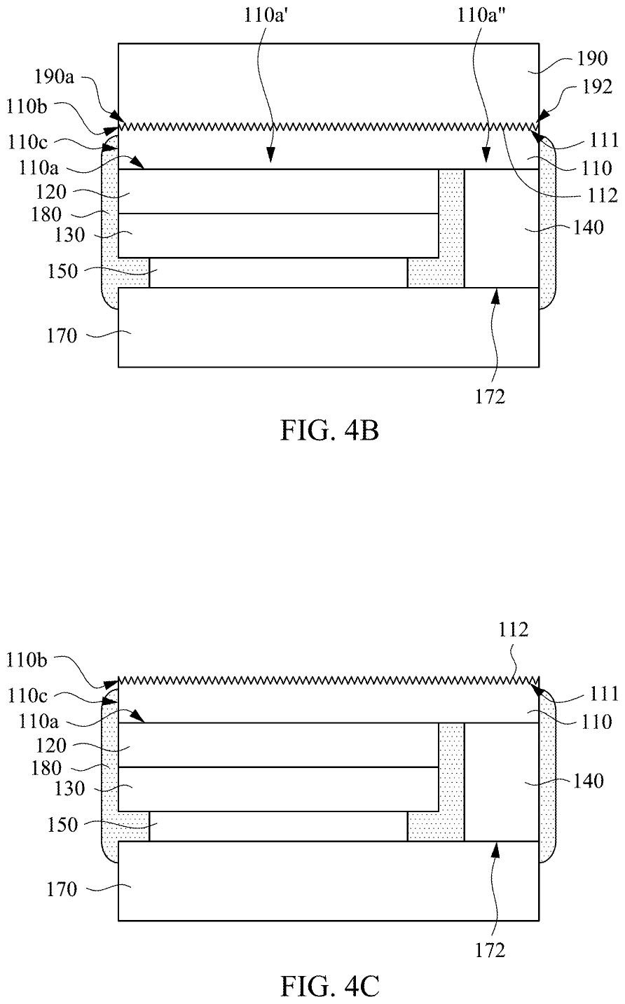

Refer to FIGS. 4A to 4C. FIGS. 4A to 4C are schematic cross-sectional views of various stages showing another process for manufacturing a micro light-emitting film structure in accordance with the first embodiment of the present disclosure. In some examples, as shown in FIG. 4A, when the micro light-emitting film structure 100 shown in FIG. 1 is manufactured, a growth substrate 190 may be provided firstly. A surface 190a of the growth substrate 190 is provided with many surface microstructures 192. The first conductivity type semiconductor film 110 is formed on the surface 190a of the growth substrate 190 by using, for example, an epitaxial growth method. The second surface 110b of the first conductivity type semiconductor film 110 is connected to the surface 190a of the growth substrate 190, and the first conductivity type semiconductor film 110 covers and is bonded to the surface microstructures 192.

Next, the light-emitting film 120 is formed on the first surface 110a of the first conductivity type semiconductor film 110 by using, for example, an epitaxial growth method. The second conductivity type semiconductor film 130 is formed on the light-emitting film 120 by using, for example, an epitaxial growth method to form a structure shown in FIG. 4A.

Then, a portion of the second conductivity type semiconductor film 130 and a portion of the light-emitting film 120 are removed by using, for example, a photolithograph process and an etching process, until the second portion 110a″ of the first surface 110a of the first conductivity type semiconductor film 110 is exposed. Next, the first contact electrode 140 may be formed on the exposed second portion 110a″ of the first surface 110a of the first conductivity type semiconductor film 110, and the second contact electrode 150 may be formed on the second conductive type semiconductor film 130 by using, for example, an evaporation method. The first contact electrode 140 and the light-emitting film 120 are physically separated from each other. The first conductive type semiconductor film 110, the light-emitting film 120, the second conductive type semiconductor film 130, the first contact electrode 140, and the second contact electrode 150 form the micro light-emitting film structure 100 shown in FIG. 1.

Then, a temporary substrate 170 may be firstly provided. As shown in FIG. 4B, the growth substrate 190 and the micro light-emitting film structure 100 formed thereon are turned upside down, and the micro light-emitting film structure 100 is bonded to the surface 172 of the temporary substrate 170 by using the adhesive material 180. The first contact electrode 140 and the second contact electrode 150 pass through the adhesive material 180, and face and are bonded to the surface 172 of the temporary substrate 170. The adhesive material 180 extends at least from the surface 172 of the temporary substrate 170 to the side surface 110c of the first conductivity type semiconductor film 110.

Subsequently, as shown in FIG. 4C, the growth substrate 160 is removed from the second surface 110b of the first conductive type semiconductor film 110 by using the temporary substrate 170 as a support. Similarly, any type of laser, such as diode-pumped solid-state laser or excimer laser, can be used, such that the growth substrate 160 can be stripped by using a laser lift-off method. The first conductive type semiconductor film 110 covers and is bonded to the surface microstructure 192 of the growth substrate 190, such that after the second surface 110b of the first conductive type semiconductor film 110 is separated from the surface microstructure 192 of the growth substrate 190, the asperity 111 including many microstructures 112 can be formed on the second surface 110b to increase the amount of the extracting light. The microstructures 112 on the second surface 110b are complementary to the surface microstructure 192 of the growth substrate 190. In some examples, when the asperity 111 is formed on the second surface 110b, a roughening treatment may be performed on the second surface 110b of the first conductive type semiconductor film 110 after the second surface 110b is separated from the surface microstructure 192 of the growth substrate 190. The roughening treatment may be performed by using, for example, a dry etching technique, a wet etching technique, or a photolithography technique. Then, the temporary substrate 170 and the adhesive material 180 may be removed to substantially complete the micro light-emitting film structure 100 shown in FIG. 1.

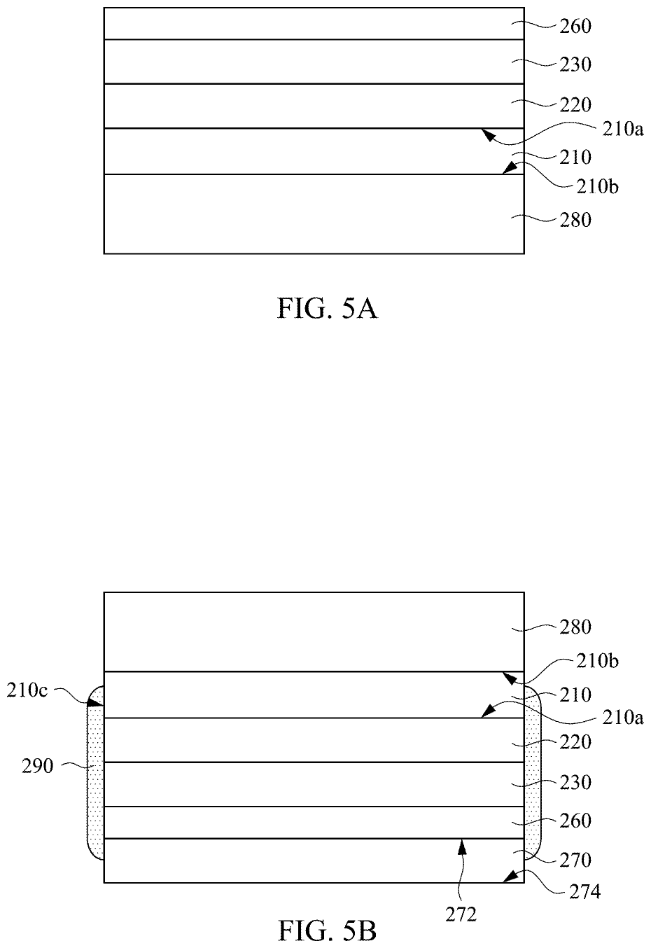

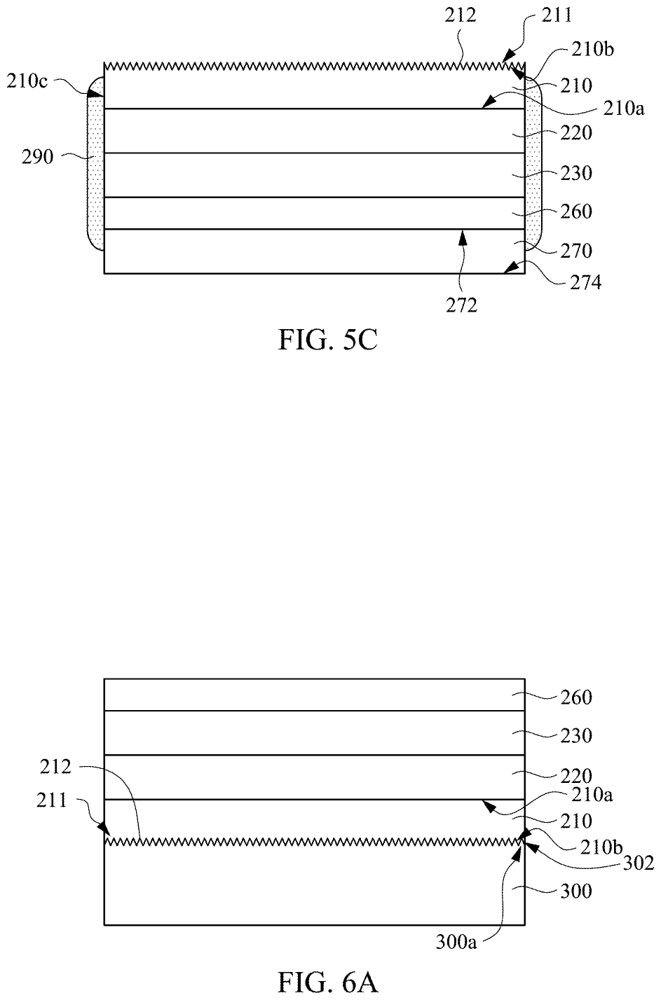

Refer to FIGS. 5A to 5C. FIGS. 5A to 5C are schematic cross-sectional views of various stages showing a process for manufacturing a micro light-emitting film structure in accordance with the second embodiment of the present disclosure. As shown in FIG. 5A, when the micro light-emitting film structure 200 shown in FIG. 2 is manufactured, a growth substrate 280 may be provided firstly. The first conductivity type semiconductor film 210 is formed on the growth substrate 280 by using, for example, an epitaxial growth method. The second surface 210b of the first conductivity type semiconductor film 210 is connected to the growth substrate 280. Next, the light-emitting film 220 is formed on the first surface 210a of the first conductivity type semiconductor film 210, and the second conductivity type semiconductor film 230 is formed on the light-emitting film 220 by using, for example, an epitaxial growth method. The reflective film 260 is formed on the second conductivity type semiconductor film 230 by using, for example, a deposition method to form a structure shown in FIG. 5A.

Then, the temporary substrate 270 may be firstly provided. In addition, as shown in FIG. 5B, the structure shown in FIG. 5A is turned upside down, and the reflective film 260 is bonded to a surface 272 of the temporary substrate 270 by using an adhesive material 290. The adhesive material 290 may be any colloid, such as laser glue and polydimethylsiloxane. The adhesive material 290 extends at least from the surface 272 of the temporary substrate 270 to a side surface 210c of the first conductivity type semiconductor film 210.

Next, the growth substrate 280 can be removed from the second surface 210b of the first conductivity type semiconductor film 210 by using the temporary substrate 270 as a support. Any type of laser, such as diode-pumped solid-state laser or excimer laser, can be used to strip the growth substrate 280.

After the growth substrate 280 is removed, the second surface 210b of the first conductivity type semiconductor film 210 may be exposed. Next, as shown in FIG. 5C, the asperity 211 is formed on the second surface 210b of the first conductivity type semiconductor film 210 to increase the amount of extracting light. The asperity 211 includes many microstructures 212. The microstructures 212 may be formed by performing a roughening treatment on the second surface 210b of the first conductive type semiconductor film 210. The roughening treatment may be performed by using, for example, a dry etching technique, a wet etching technique, or a photolithography technique. For example, a reactive ion etching process may be used to form the asperity 211. During the roughening treatment, the etching process or the photolithography process may be controlled, so that the height difference of relief of the asperity 211 is less than or equal to 1 μm.

The adhesive material 290 extends to cover at least a portion of the side surface 210c of the first conductive type semiconductor film 210, such that when the second surface 210b of the first conductive type semiconductor film 210 is roughened, the adhesive material 290 can protect a portion of the first conductive type semiconductor film 210 as well as the underlying light emitting film 220 and the second conductive type semiconductor film 230 from damage. Thus, the process yield is enhanced.

Then, the adhesive material 290 may be removed. The first contact electrode 240 may be formed on a portion of the second surface 210b of the first conductivity type semiconductor film 210 by using, for example, an evaporation method. Similarly, the second contact electrode 250 may be formed on a surface 274 of the temporary substrate 270 by using, for example, an evaporation method, to substantially complete the micro light-emitting film structure 200 shown in FIG. 2. The surfaces 272 and 274 of the temporary substrate 270 are opposite to each other, such that the temporary substrate 270 is located between the reflective film 260 and the second contact electrode 250. The formation sequence of the first contact electrode 240 and the second contact electrode 250 may be adjusted according to requirements.

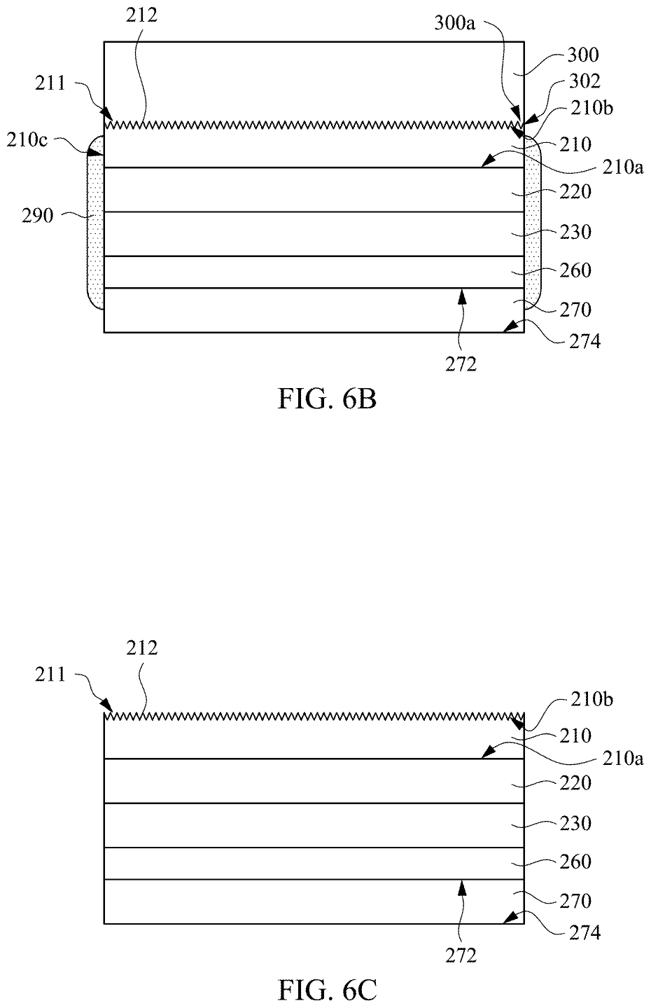

Refer to FIGS. 6A to 6C. FIGS. 6A to 6C are schematic cross-sectional views of various stages showing another process for manufacturing a micro light-emitting film structure in accordance with the second embodiment of the present disclosure. In some examples, as shown in FIG. 6A, when the micro light-emitting film structure 200 shown in FIG. 2 is manufactured, a growth substrate 300 may be provided firstly. A surface 300a of the growth substrate 300 is provided with many surface microstructures 302. The first conductivity type semiconductor film 210 is formed on the growth substrate 300 by using, for example, an epitaxial growth method. The second surface 210b of the first conductivity type semiconductor film 210 is connected to the growth substrate 300, and the first conductivity type semiconductor film 210 covers and is bonded to the surface microstructures 302.

Next, the light-emitting film 220 is formed on the first surface 210a of the first conductivity type semiconductor film 210, and the second conductivity type semiconductor film 230 is formed on the light-emitting film 220 by using, for example, an epitaxial growth method. The reflective film 260 is formed on the second conductivity type semiconductor film 230 by using, for example, a deposition method to form a structure shown in FIG. 6A.

Then, the temporary substrate 270 may be firstly provided. As shown in FIG. 6B, the structure shown in FIG. 6A is turned upside down, and the reflective film 260 is bonded to the surface 272 of the temporary substrate 270 by using an adhesive material 290. The adhesive material 290 extends at least from the surface 272 of the temporary substrate 270 to the side surface 210c of the first conductivity type semiconductor film 210.

Next, the growth substrate 300 can be removed from the second surface 210b of the first conductivity type semiconductor film 210 by using the temporary substrate 270 as a support. Similarly, any type of laser, such as diode-pumped solid-state laser or excimer laser, can be used, such that the growth substrate 300 can be stripped by using a laser lift-off method. The first conductive type semiconductor film 210 covers and is bonded to the surface microstructure 302 of the growth substrate 300, such that after the second surface 210b of the first conductive type semiconductor film 210 is separated from the surface microstructure 302 of the growth substrate 300, the asperity 211 including many microstructures 212 can be formed on the second surface 210b, in which the microstructures 212 are complementary to the surface microstructure 302, as shown in FIG. 6C. By forming the asperity 211 on the second surface 210b, the light extraction efficiency can be enhanced.

In some examples, when the asperity 211 is formed on the second surface 210b, a roughening treatment may be performed on the second surface 210b of the first conductive type semiconductor film 210 after the second surface 210b is separated from the surface microstructure 302 of the growth substrate 300. The roughening treatment may be performed by using, for example, a dry etching technique, a wet etching technique, or a photolithography technique.

Then, the adhesive material 290 may be removed. Subsequently, the first contact electrode 240 may be formed on a portion of the second surface 210b of the first conductivity type semiconductor film 210, and the second contact electrode 250 may be formed on a surface 274 of the temporary substrate 270 by using, for example, an evaporation method, to substantially complete the micro light-emitting film structure 200 shown in FIG. 2.

According to the aforementioned embodiments, one advantage of the present disclosure is that when an adhesive material is used to bond a micro light-emitting film structure on a surface of a temporary substrate, the adhesive material covers a side surface of a first conductive semiconductor film, such that when a light-extracting surface of the first conductivity type semiconductor film is roughened, the films underlying the first conductivity type semiconductor film are prevented from being damaged, thereby increasing the process yield.

Another advantage of the present disclosure is that a light-extracting surface of a first conductivity type semiconductor film may be provided with a asperity including many microstructures, such that the internal reflection of the micro light-emitting film structure is reduced, and the light extraction rate of the micro light-emitting film structure is effectively enhanced, thereby increasing the brightness of the micro light-emitting film structure.

Although the present disclosure has been described in considerable detail with reference to certain embodiments thereof, the foregoing embodiments of the present disclosure are illustrative of the present disclosure rather than limiting of the present disclosure. It will be apparent to those having ordinary skill in the art that various modifications and variations can be made to the present disclosure without departing from the scope or spirit of the disclosure. Therefore, the spirit and scope of the appended claims should not be limited to the description of the embodiments contained herein.

What is claimed is:

1. A micro light-emitting film structure, comprising:
a first conductivity type semiconductor film having a first surface and a second surface, which are opposite to each other, wherein the second surface of the first conductivity type semiconductor film comprises an asperity, and a height difference of relief of the asperity is less than or equal to 1 μm;
a light-emitting film disposed on the first surface of the first conductivity type semiconductor film;
a second conductivity type semiconductor film connected to the light-emitting film, wherein the light-emitting film is sandwiched between the second conductivity type semiconductor film and the first conductivity type semiconductor film, and a conductivity type of the first conductivity type semiconductor film is different from a conductivity type of the second conductivity type semiconductor film;
a first contact electrode connected to the first conductivity type semiconductor film; and
a second contact electrode connected to the second conductivity type semiconductor film,
wherein a length or a diameter of the micro light-emitting film structure is less than 100 μm, and a thickness of the micro light-emitting film structure is equal to or less than 10 μm.

2. The micro light-emitting film structure of claim 1, wherein the asperity comprises a plurality of microstructures, each of the microstructures comprises a top and a bottom, and a height difference from the top to the bottom of each of the microstructures is between 600 nm and 1 μm.

3. The micro light-emitting film structure of claim 1, wherein the asperity comprises a plurality of microstructures, each of the microstructures comprises a top and a bottom, and a height difference from the top to the bottom of each of the microstructures is between 200 nm and 1 μm.

4. The micro light-emitting film structure of claim 1, wherein the first conductivity type semiconductor film is an N-type GaN film, and the second conductivity type semiconductor film is a P-type GaN film.

5. The micro light-emitting film structure of claim 1, wherein the first surface of the first conductivity type semiconductor film comprises a first portion and a second portion, the light-emitting film is disposed on the first portion of the first surface, and the first contact electrode is disposed on the second portion of the first surface and is physically separated from the light-emitting film.

6. The micro light-emitting film structure of claim 1, wherein the first contact electrode is disposed on a portion of the second surface of the first conductivity type semiconductor film, the second contact electrode and the first contact electrode are respectively located at two opposite sides of the second conductivity type semiconductor film, and the micro light-emitting film structure further comprises:
a reflective film disposed between the second conductivity type semiconductor film and the second contact electrode; and
a temporary substrate sandwiched between the reflective film and the second contact electrode.

7. A method for manufacturing a micro light-emitting film structure, comprising:
forming a first conductivity type semiconductor film on a growth substrate, wherein the first conductivity type semiconductor film has a first surface and a second surface, which are opposite to each other, the first surface comprises a first portion and a second portion, and the second surface is connected to the growth substrate;
forming a light-emitting film on the first portion of the first surface of the first conductivity type semiconductor film;
forming a second conductivity type semiconductor film on the light-emitting film, wherein a conductivity type of the first conductivity type semiconductor film is different from a conductivity type of the second conductivity type semiconductor film;
forming a first contact electrode on the second portion of the first surface of the first conductivity type semiconductor film, wherein the first contact electrode is physically separated from the light-emitting film;
forming a second contact electrode on the second conductivity type semiconductor film, wherein the first conductivity type semiconductor film, the light-emitting film, the second conductivity type semiconductor film, the first contact electrode, and the second contact electrode form a micro light-emitting film structure;
bonding the micro light-emitting film structure onto a surface of a temporary substrate by using an adhesive material, wherein the first contact electrode and the second contact electrode face the surface and are bonded to the surface, the adhesive material extends at least from the surface to a side surface of the first conductivity type semiconductor film;
removing the growth substrate;
forming an asperity on the second surface of the first conductivity type semiconductor film, wherein a height difference of relief of the asperity is less than or equal to 1 μm;
removing the temporary substrate; and
removing the adhesive material.

8. The method of claim 7, wherein the asperity comprises a plurality of microstructures, each of the microstructures comprises a top and a bottom, and a height difference from the top to the bottom of each of the microstructures is between 200 nm and 1 μm.

9. The method of claim 7, wherein the first conductivity type semiconductor film is an N-type GaN film, and the second conductivity type semiconductor film is a P-type GaN film.

10. The method of claim 7, wherein forming the asperity comprises performing a roughening treatment on the second surface of the first conductivity type semiconductor film.

11. The method of claim 10, wherein performing the roughening treatment comprises using a dry etching technique, a wet etching technique, or a photolithograph technique.

12. The method of claim 7, wherein the growth substrate comprises a plurality of surface microstructures, forming the first conductivity type semiconductor film comprises covering and bonding the surface microstructures with the second surface of the first conductivity type semiconductor film, and forming the asperity comprises separating the second surface from the surface microstructures.

13. The method of claim 12, wherein forming the asperity further comprises performing a roughening treatment on the second surface of the first conductivity type semiconductor film after the second surface is separated from the surface microstructures.

14. A method for manufacturing a micro light-emitting film structure, comprising:
forming a first conductivity type semiconductor film on a growth substrate, wherein the first conductivity type semiconductor film has a first surface and a second surface, which are opposite to each other, and the second surface is connected to the growth substrate;
forming a light-emitting film on the first surface of the first conductivity type semiconductor film;
forming a second conductivity type semiconductor film on the light-emitting film, wherein a conductivity type of the first conductivity type semiconductor film is different from a conductivity type of the second conductivity type semiconductor film;
forming a reflective film on the second conductivity type semiconductor film;
bonding the reflective film onto a surface of a temporary substrate by using an adhesive material, wherein the adhesive material extends at least from the surface to a side surface of the first conductivity type semiconductor film;
removing the growth substrate;
forming an asperity on the second surface of the first conductivity type semiconductor film, wherein a height difference of relief of the asperity is less than or equal to 1 μm;
forming a first contact electrode on a portion of the second surface of the first conductivity type semiconductor film; and
forming a second contact electrode on the temporary substrate, wherein the temporary substrate is located between the reflective film and the second contact electrode.

15. The method of claim 14, wherein the asperity comprises a plurality of microstructures, each of the microstructures comprises a top and a bottom, and a height difference from the top to the bottom of each of the microstructures is between 200 nm and 1 μm.

16. The method of claim 14, wherein the first conductivity type semiconductor film is an N-type GaN film, and the second conductivity type semiconductor film is a P-type GaN film.

17. The method of claim 14, wherein forming the asperity comprises performing a roughening treatment on the second surface of the first conductivity type semiconductor film.

18. The method of claim 17, wherein performing the roughening treatment comprises using a dry etching technique, a wet etching technique, or a photolithograph technique.

19. The method of claim 14, wherein the growth substrate comprises a plurality of surface microstructures, forming the first conductivity type semiconductor film comprises covering and bonding the surface microstructures with the second surface of the first conductivity type semiconductor film, and forming the asperity comprises separating the second surface from the surface microstructures.

20. The method of claim 19, wherein forming the asperity further comprises performing a roughening treatment on the second surface of the first conductivity type semiconductor film after the second surface is separated from the surface microstructures.
